(19) United States
(12) Patent Application Publication
(10) Pub. No.: US 2024/0368802 A1
(43) Pub. Date: Nov. 7, 2024

(54) PRODUCTION METHOD FOR SILICON MONOCRYSTAL AND PRODUCTION METHOD FOR SILICON WAFER

(71) Applicant: SUMCO CORPORATION, Tokyo (JP)

(72) Inventors: Wataru SUGIMURA, Tokyo (JP); Hideki SAKAMOTO, Tokyo (JP); Ryusuke YOKOYAMA, Tokyo (JP)

(73) Assignee: SUMCO CORPORATION, Tokyo (JP)

(21) Appl. No.: 18/689,143

(22) PCT Filed: Jun. 15, 2022
(86) PCT No.: PCT/JP2022/023972

§ 371 Date: Mar. 5, 2024

(30) Foreign Application Priority Data
Sep. 10, 2021 (JP) 2021-147997

(51) Int. Cl. C30B 15/14; C30B 15/20; C30B 29/06; C30B 30/04; C30B 33/00

(52) U.S. Cl. CPC C30B 15/14; C30B 15/20; C30B 29/06; C30B 30/04; C30B 33/00

(57) ABSTRACT

A method of manufacturing monocrystalline silicon includes: setting a first resistance value that is a resistance value of a first power supply portion and a second resistance value that is a resistance value of a second power supply portion; heating a silicon melt in a quartz crucible in a magnetic-field-free state; applying a horizontal magnetic field to the silicon melt in the quartz crucible; and pulling up the monocrystalline silicon from the silicon melt. The setting of the resistance values includes: measuring the first resistance value and the second resistance value; adjusting, when a resistance ratio therebetween is less than a determination value, at least one of the first resistance value or the second resistance value; measuring again the resistance values and comparing the resistance ratio with the determination value; and ending the setting when the resistance ratio is greater than or equal to the determination value.

### TECHNICAL FIELD

The present invention relates to a method of manufacturing monocrystalline silicon and a method of manufacturing a silicon wafer.

### BACKGROUND ART

A method called Czochralski method (hereinafter abbreviated as a CZ method) is used for manufacturing monocrystalline silicon. In the manufacturing method using the CZ method, when a horizontal magnetic field is applied externally, a silicon melt initially has either a clockwise vortex state or an anticlockwise vortex state with respect to the magnetic-field application direction. A direction of the vortex is random, so that an oxygen concentration taken into the crystal varies depending on the direction of the vortex and an environment inside a furnace. In order to obtain monocrystalline silicon having a stable oxygen concentration, controlling a convection pattern of the silicon melt during pulling is important. For this reason, various studies have been made on a method of controlling the convection pattern of the silicon melt in a crucible (for example, see, Patent Literature 1).

In a method of controlling a convection pattern of a silicon melt disclosed in Patent Literature 1, an imaginary line is set that is parallel to a central magnetic field line of a horizontal magnetic field and passes through a center of a surface of the silicon melt when a crucible is viewed from vertically above. The silicon melt is heated with use of a heating portion whose heating capacity differs on both sides across the imaginary line and the horizontal magnetic field is applied to the silicon melt, thereby fixing a direction of convection in a cross section orthogonal to the magnetic field.

### CITATION LIST

### Patent Literature(s)

Patent Literature 1 : International Publication WO2019/167989

### SUMMARY OF THE INVENTION

### Problem(s) to be Solved by the Invention

Even when a method of controlling a convection pattern of a silicon melt disclosed in Patent Literature 1 is employed, there is a possibility that convection cannot be stably controlled because an environment inside a furnace changes due to, for example, aging deterioration of members in the furnace when actually manufacturing monocrystalline silicon. Thus, there is a possibility that monocrystalline silicon having a stable oxygen concentration cannot be manufactured, and that a silicon wafer cut out from the monocrystalline silicon may also be degraded.

An object of the invention is to provide a method of manufacturing monocrystalline silicon and a method of manufacturing a silicon wafer that make it possible to stably control a direction of convection of a silicon melt and to respectively manufacture the monocrystalline silicon and the silicon wafer each having a stable oxygen concentration.

### Means for Solving the Problem(s)

According to an aspect of the invention, there is provided a method of manufacturing monocrystalline silicon of pulling up monocrystalline silicon from a silicon melt in a quartz crucible, the silicon melt having been heated using a heating device, the heating device including a heat generating portion disposed around the quartz crucible, and power supply portions configured to supply electric power to the heat generating portion, the power supply portions including, in a case where the heating device is divided into a first heating region and a second heating region by a central magnetic field line of a horizontal magnetic field passing through a center axis of the quartz crucible viewed from vertically above, a first power supply portion disposed in the first heating region and a second power supply portion disposed in the second heating region, the method including: setting a first resistance value that is a resistance value of the first power supply portion and a second resistance value that is a resistance value of the second power supply portion; heating the silicon melt in the quartz crucible in a magnetic-field-free state; applying a horizontal magnetic field to the silicon melt in the quartz crucible; and pulling up the monocrystalline silicon from the silicon melt, in which the setting of the resistance values includes: measuring the first resistance value and the second resistance value, determining whether a resistance ratio is greater than or equal to a determination value that has been set in advance, the resistance ratio being a value obtained by dividing a higher resistance value by a lower resistance value out of the first resistance value and the second resistance value, and adjusting, in a case where it is determined in the determination that the resistance ratio is less than the determination value, at least one of the first resistance value or the second resistance value, executing again, in the case where it is determined in the determination that the resistance ratio is less than the determination value, the determination after executing the adjustment and the measurement; and ending the setting of the resistance values in a case where it is determined in the determination that the resistance ratio is greater than or equal to the determination value.

In the method of manufacturing the monocrystalline silicon according to the aspect of the invention, it is preferable that the setting of the resistance values is executed every time the pull-up of the monocrystalline silicon is executed a predetermined number of times.

In the method of manufacturing the monocrystalline silicon according to the aspect of the invention, it is preferable that the predetermined number of times is greater than or equal to 1 and less than or equal to 50.

In the method of manufacturing the monocrystalline silicon according to the aspect of the invention, it is preferable that the determination value is greater than or equal to 1.2.

In the method of manufacturing the monocrystalline silicon according to the aspect of the invention, it is preferable that the measurement includes: measuring a combined resistance of the heat generating portion and the power supply portions, measuring a combined resistance of the heat generating portion, and calculating the first resistance value and the second resistance value based on respective resistance values obtained by the measurements.

In the method of manufacturing the monocrystalline silicon according to the aspect of the invention, it is preferable that the power supply portions each include a terminal integrally provided with the heat generating portion, and an electrode having one end connected to the terminal and the other end connected to a power source, and the adjustment includes decreasing a resistance value of one of the power supply portions by disposing a conductive sheet between the terminal and the electrode.

In the method of manufacturing the monocrystalline silicon according to the aspect of the invention, it is preferable that the power supply portions each include: a terminal connected to the heat generation portion; and an electrode having one end connected to the terminal and the other end connected to a power source, and the adjustment includes increasing a resistance value of one of the power supply portions by roughening a contact surface between the terminal and the electrode.

In the method of manufacturing the monocrystalline silicon according to the aspect of the invention, it is preferable that the power supply portions each include: a terminal connected to the heat generation portion; and an electrode having one end connected to the terminal and the other end connected to a power source, an electrical resistance adjuster having a plate shape is interposed between the terminal and the electrode, and the adjustment includes adjusting a resistance value by making the number of electrical resistance adjusters to be interposed between the terminal and the electrode of the first power supply portion different from the number of electrical resistance adjusters to be interposed between the terminal and the electrode of the second power supply portion, or by making a thickness dimension of the electrical resistance adjuster to be interposed between the terminal and the electrode of the first power supply portion different from a thickness dimension of the electrical resistance adjuster to be interposed between the terminal and the electrode of the second power supply portion.

According to another aspect of the invention, there is provided a method of manufacturing a silicon wafer, the method including manufacturing the silicon wafer by cutting out the silicon wafer from the monocrystalline silicon having been pulled up with use of the method of manufacturing the monocrystalline silicon according to the above aspect of the invention.

According to the aspects of the invention, it is possible to stably control a direction of convection of the silicon melt and to manufacture the monocrystalline silicon and the silicon wafer each having a stable oxygen concentration.

### BRIEF EXPLANATION OF DRAWINGS

FIG. 1 is a vertical cross-sectional view of a schematic configuration of a monocrystalline silicon manufacturing apparatus according to an exemplary embodiment of the invention.

FIG. 2 is a perspective view of a main part of a heating device according to the exemplary embodiment of the invention.

FIG. 3 is a schematic plan view of the heating device and a magnetic-field applying portion according to the exemplary embodiment of the invention.

FIG. 4 is a schematic view of a configuration of the heating device and a horizontal-magnetic-field application state according to the exemplary embodiment of the invention.

FIG. 5 is a schematic view of an arrangement of a temperature sensor according to the exemplary embodiment of the invention.

FIG. 6A is a schematic view illustrating a connection structure between a terminal and an electrode according to the exemplary embodiment of the invention, and is a partially cutaway front elevational view.

FIG. 6B is a schematic view illustrating the connection structure between the terminal and the electrode according to the exemplary embodiment of the invention, and is a plan view of a conductive sheet.

FIG. 7 is an equivalent circuit diagram of the heating device according to the exemplary embodiment of the invention.

FIG. 8 is a block diagram illustrating a control device of the monocrystalline silicon manufacturing apparatus according to the exemplary embodiment of the invention.

FIG. 9 is a flowchart illustrating an exemplary method of manufacturing monocrystalline silicon according to the exemplary embodiment of the invention.

FIG. 10 is a flowchart illustrating a resistance value setting step in FIG. 9.

FIG. 11 is a flowchart illustrating a measurement step in FIG. 10.

FIG. 12 is a flowchart illustrating an adjustment step in FIG. 10.

FIG. 13 is a flowchart illustrating a silicon-melt heating step in FIG. 9.

### DESCRIPTION OF EMBODIMENT(S)

### Monocrystalline Silicon Manufacturing Apparatus

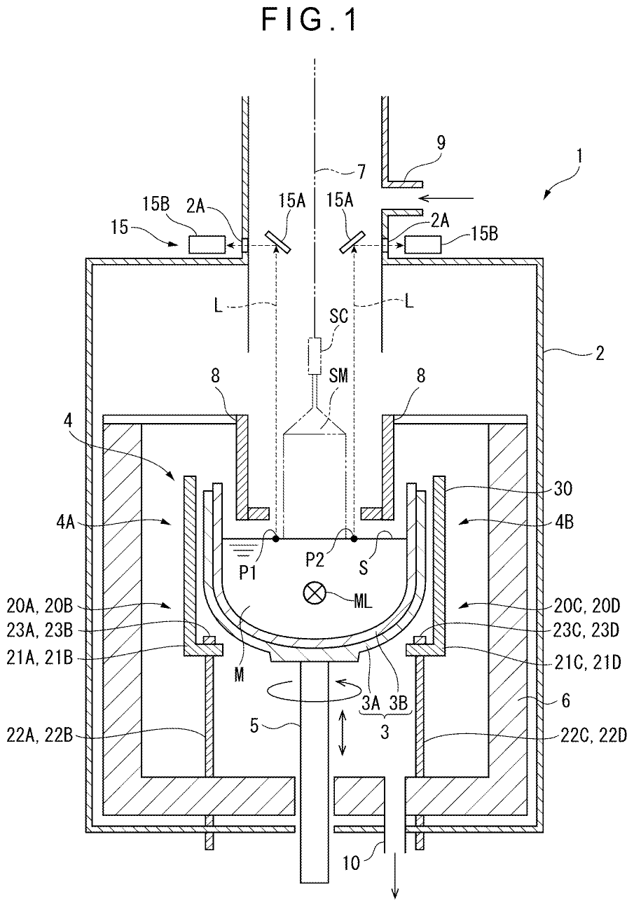

FIG. 1 is a vertical cross-sectional view of a schematic configuration of a monocrystalline silicon manufacturing apparatus 1 applicable to a method of manufacturing monocrystalline silicon according to an exemplary embodiment of the invention.

The monocrystalline silicon manufacturing apparatus 1 is an apparatus for pulling up monocrystalline silicon SM by the CZ method, and includes a chamber 2 forming an outer shell, a crucible 3 disposed in a central portion of the chamber 2, and a heating device 4 disposed around an inside of the crucible 3.

The crucible 3 has a double-layered structure including a graphite crucible 3A on an outer side and a quartz crucible 3B on an inner side, and a silicon melt M (a raw material melt) is contained in the quartz crucible 3B. The graphite crucible 3A and the quartz crucible 3B are each a bottomed cylindrical container, and each have a circular shape in a plan view when viewed from vertically above. The crucible 3 is fixed to an upper end of a support shaft 5 that is rotatable and movable upward and downward.

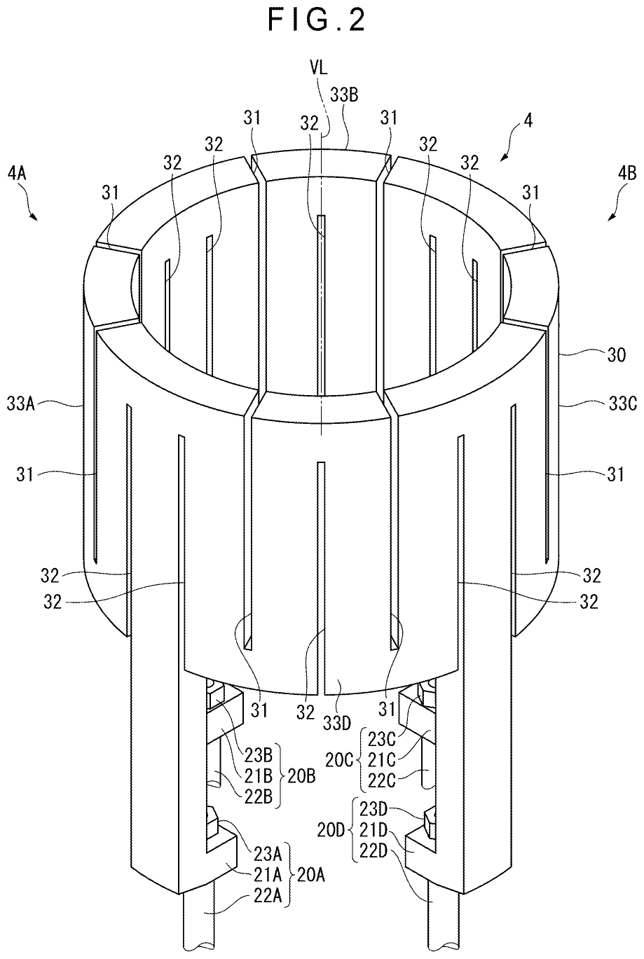

As illustrated in FIG. 2, the heating device 4 is a graphite heater having a substantially cylindrical shape and disposed around the crucible 3. Details thereof will be described later. As illustrated in FIG. 1, a heat insulation material 6 is provided outside the heating device 4 along an inner surface of the chamber 2.

Above the crucible 3, a pull-up shaft 7 is disposed coaxially with the support shaft 5. The pull-up shaft 7, which is formed from a wire or the like, rotates at a predetermined rate in a direction that is opposite to or is the same as a rotational direction of the support shaft 5. A seed crystal SC is attached to a lower end of the pull-up shaft 7.

Inside the chamber 2, a hollow cylindrical heat shield 8 is disposed above the silicon melt M in the crucible 3 to surround the growing monocrystalline silicon SM.

The heat shield 8 shields the growing monocrystalline silicon SM from radiant heat from the silicon melt M in the crucible 3 and radiant heat from side walls of the heating device 4 and the crucible 3, and inhibits outward heat diffusion from a solid-liquid interface that is an interface on which crystal grows and a vicinity thereof, whereby the heat shield 8 serves to control a temperature gradient of a central portion and an outer peripheral portion of the monocrystalline silicon SM in a direction of the pull-up shaft 7.

A gas inlet 9, through which an inert gas such as argon gas is introduced into the chamber 2, is provided at an upper part of the chamber 2. An exhaust outlet 10, through which the gas in the chamber 2 is sucked and discharged when an unillustrated vacuum pump is driven, is provided at a lower part of the chamber 2.

The inert gas introduced into the chamber 2 through the gas inlet 9 flows downward between the growing monocrystalline silicon SM and the heat shield 8, flows into a space between a lower end of the heat shield 8 and a liquid surface of the silicon melt M, flows toward an outside of the heat shield 8 and an outside of the crucible 3, and thereafter flows downward along the outside of the crucible 3, to be discharged from the exhaust outlet 10.

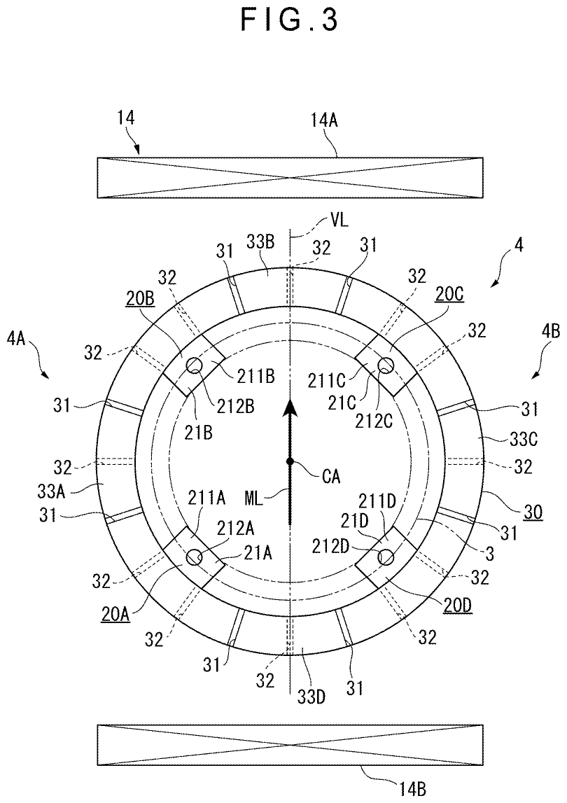

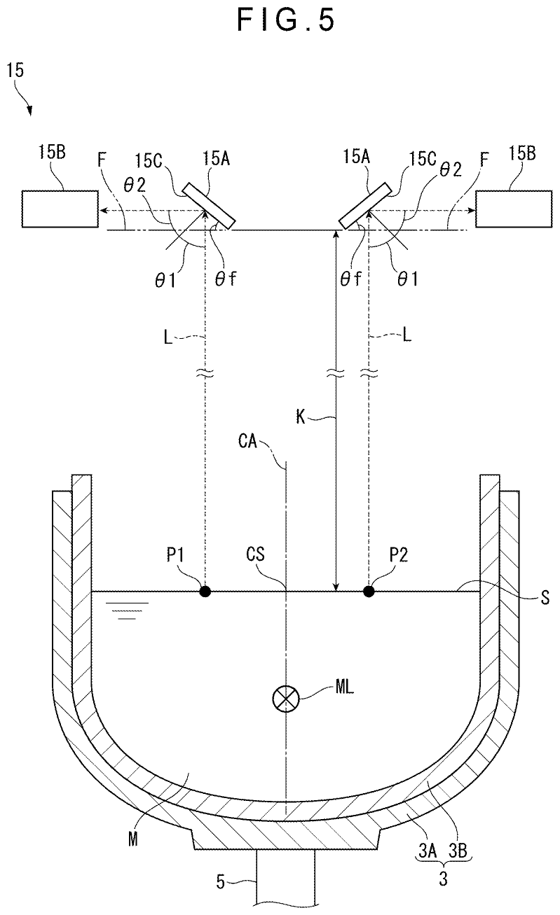

The monocrystalline silicon manufacturing apparatus 1 includes a magnetic-field applying portion 14 illustrated in FIG. 3 and a temperature sensor 15 illustrated in FIGS. 1 and 5.

The magnetic-field applying portion 14 includes a first magnetic body 14A and a second magnetic body 14B each in a form of an electromagnetic coil. The first and second magnetic bodies 14A and 14B are provided outside the chamber 2 in such a manner as to be opposed to each other with the crucible 3 interposed therebetween. In the example of FIG. 3, the magnetic-field applying portion 14 applies a horizontal magnetic field in such a manner that, in a plan view when viewed from vertically above, a magnetic-field center line (a central magnetic field line of the horizontal magnetic field) passing through a coil center axis intersects with a heat generating portion 30 having a cylindrical shape and a center axis CA of the crucible 3, and is in a direction from the second magnetic body 14B toward the first magnetic body 14A (an upper direction indicated by an arrow ML in FIG. 3, and a direction from a nearby side to a far side on a sheet in FIG. 1). However, the magnetic-field center line does not necessarily pass an intersection CS of the center axis CA of the crucible 3 on a melt surface of the silicon melt M. That is, a height position of the magnetic-field center line is not particularly limited, and may be an inside or an outside of the silicon melt M depending on the quality of the monocrystalline silicon SM.

As illustrated in FIG. 5, the center axis of the crucible 3 is defined as “CA”, the surface of the silicon melt M in the crucible 3 is defined as “S”, and the center of the surface S is defined as “CS”. As illustrated in FIG. 3, in a plan view of the crucible 3 and the heating device 4 viewed from vertically above, an imaginary line along the magnetic-field center line that intersects with the center axis CA of the crucible 3 is defined as “VL”. The imaginary line VL is thus a line that passes through the center axis CA of the crucible 3 and extends along the arrow ML from the second magnetic body 14B toward the first magnetic body 14A.

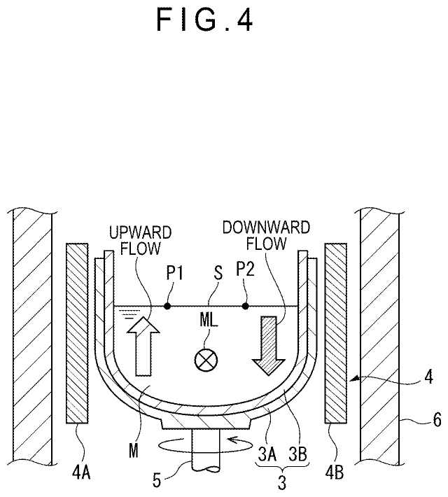

The temperature sensor 15 measures temperatures at a first measurement point P1 and a second measurement point P2 as illustrated in FIGS. 1, 4, and 5. As illustrated in FIG. 1, a position of each of the first measurement point P1 and the second measurement point P2 in a radial direction is set between an outer circumferential surface of the monocrystalline silicon SM to be grown and an inner circumferential surface of an opening of the heat shield 8, and an intermediate position thereof is particularly preferable. In the exemplary embodiment, the first measurement point P1 and the second measurement point P2 are set at point-symmetric positions with respect to the center CS of the surface S. As will be described later, measurement of the temperatures at the measurement points P1 and P2 makes it possible to confirm, for example, a direction of convection of the silicon melt M. For example, when heating of the silicon melt M by the heating device 4 fixes the direction of the convection of the silicon melt M to clockwise, that is, a clockwise vortex in FIG. 4, a measurement temperature at the first measurement point P1 is higher than a measurement temperature at the second measurement point P2. Further, when heating of the silicon melt M by the heating device 4 fixes the direction of the convection of the silicon melt M to counterclockwise, that is, a counterclockwise vortex, the measurement temperature at the first measurement point P1 is lower than the measurement temperature at the second measurement point P2. Note that FIG. 4 is an example in which an upward flow is fixed to a left side of the crucible 3, a downward flow is fixed to a right side of the crucible 3, and the direction of the convection of the silicon melt M is clockwise, that is, fixed to the clockwise vortex.

As illustrated in FIGS. 1 and 5, the temperature sensor 15 includes a pair of reflectors 15A and a pair of radiation thermometers 15B.

The reflectors 15A are provided inside the chamber 2. As illustrated in FIG. 5, the reflectors 15A are preferably provided in such a manner that a distance (a height) K from each of lower ends of the reflectors 15A to the surface S of the silicon melt M is in a range from 600 mm to 5,000 mm. Further, the reflectors 15A are preferably provided in such a manner that an angle θf between a reflection surface 15C of each of the reflectors 15A and a horizontal plane F is in a range from 40 degrees to 50 degrees.

With this configuration, a sum of an incidence angle θ1 and a reflection angle θ2 of radiation light L outputted vertically upward from each of the first measurement point P1 and the second measurement point P2 is in a range from 80 degrees to 100 degrees. As the reflectors 15A, silicon mirrors each having a mirror-polished surface to serve as the reflection surface 15C are preferably used, from a viewpoint of heat resistance.

The radiation thermometers 15B are provided outside the chamber 2. The radiation thermometers 15B receive the radiation light L incident through quartz windows 2A (see FIG. 1) provided for the chamber 2, and measure the temperatures at the first measurement point P1 and the second measurement point P2 in a non-contact manner.

### Heating Device

As illustrated in FIGS. 2 and 3, the heating device 4 includes the heat generating portion 30, and 2n-number (n is an integer of 2 or more) of power supply portions that supply electric power to the heat generating portion 30. In the exemplary embodiment, four power supply portions 20A, 20B, 20C and 20D are provided.

The heat generating portion 30, which is a cylindrical graphite heater, has a uniform thickness over an entire circumferential direction. The heat generating portion 30 includes multiple upper slits 31 extending downward from an upper end and multiple lower slits 32 extending upward from a lower end in the circumferential direction. A width dimension of the upper slits 31 is the same as that of the lower slits 32, and a cut depth along a vertical direction of the upper slits 31 is the same as that of the lower slits 32. Further, intervals between the upper slits 31 and the lower slits 32 are constant over an entire circumference of the heat generating portion 30.

As illustrated in FIG. 3, the heat generating portion 30 is imaginarily divided into two parts, right and left, in a plan view by an imaginary line VL passing through the center axis CA of the heat generating portion 30. The heating device 4 thus includes, in FIG. 3, a first heating region 4A located on a left side of the imaginary line VL and a second heating region 4B located on a right side of the imaginary line VL.

The first heating region 4A and the second heating region 4B have the same total number of the upper slits 31 and the lower slits 32. In the example of FIGS. 2 and 3, the first heating region 4A has four upper slits 31 and six lower slits 32, and thus, the total number of the upper slits 31 and the lower slits 32 is 10. Further, the second heating region 4B has four upper slits 31 and six lower slits 32, and thus, the total number of the upper slits 31 and the lower slits 32 is 10. Note that two lower slits 32 straddle the imaginary line VL between the first heating region 4A and the second heating region 4B. Accordingly, the number of each of the two lower slits 32 included in each of the heating regions 4A and 4B is set to 0.5. Two lower slits 32 extend over the heating regions 4A and 4B, and thus one (0.5×2=1) lower slit 32 is disposed over each of the heating regions 4A and 4B.

As illustrated in FIG. 2, the power supply portions 20A to 20D include four terminals 21A, 21B, 21C, and 21D, four electrodes 22A, 22B, 22C, and 22D, and four nuts 23A to 23D. As also illustrated in FIG. 3, the power supply portions 20A to 20D are disposed at 90-degree intervals along the circumferential direction of the heat generating portion 30. In the exemplary embodiment, the power supply portions 20A and 20B disposed in the first heating region 4A serve as a first power supply portion, and the power supply portions 20C and 20D disposed in the second heating region 4B serve as a second power supply portion.

The terminals 21A to 21D each extend downward from a lower end of a portion partitioned by two lower slits 32, and are each integrally provided with the heat generating portion 30. Further, the terminals 21A to 21D include connecting portions 211A to 211D that are each bent inward at a right angle from a lower end. The connecting portions 211A to 211D have through holes 212A to 212D.

The heating device 4 of the exemplary embodiment therefore includes a graphite heater in which the heat generating portion 30 having the cylindrical shape that is a heater element and the terminals 21A to 21D that are heater foots are integrally molded.

The heat generating portion 30 is partitioned into first to fourth curve portions 33A to 33D each having a zigzag shape with the upper slits 31 and the lower slits 32 provided therein. The first to fourth curve portions 33A to 33D configure four heater elements.

Specifically, two upper slits 31 and three lower slits 32 are alternately provided between the terminal 21A and the terminal 21B to provide the first curve portion 33A. Similarly, two upper slits 31 and three lower slits 32 are alternately provided between the terminal 21B and the terminal 21C to provide the second curve portion 33B.

Two upper slits 31 and three lower slits 32 are alternately provided between the terminal 21C and the terminal 21D to provide the third curve portion 33C. Two upper slits 31 and three lower slits 32 are alternately provided between the terminal 21D and the terminal 21A to provide the fourth curve portion 33D.

The electrodes 22A to 22D are each a rod-shaped carbon electrode, one end of which is coupled to the corresponding one of the terminals 21A to 21D and the other end of which is coupled to a power source.

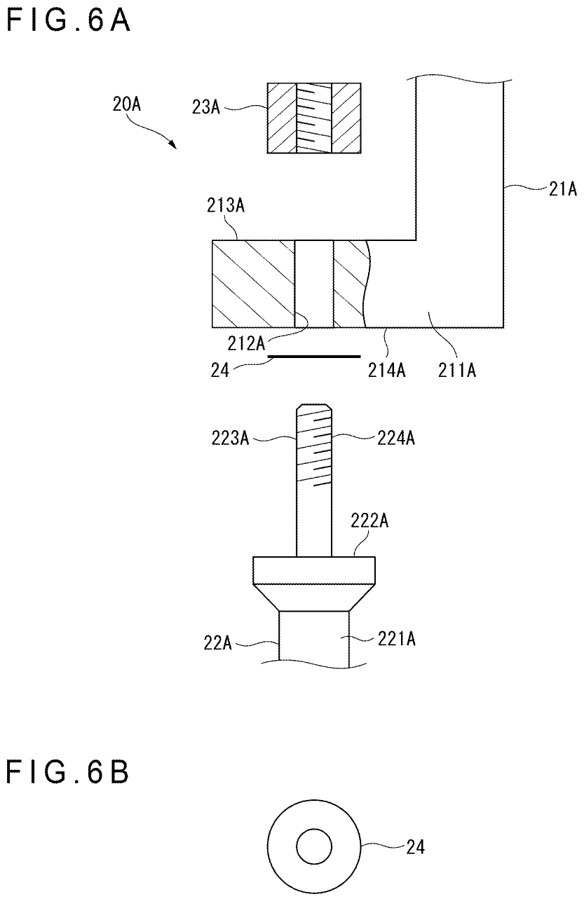

Referring to FIGS. 6A and 6B, a connection structure between the terminal 21A and the electrode 22A is described.

As illustrated in FIG. 6A, the electrode 22A includes a body 221A, and an insertion portion 223A protruding upward from a top surface 222A of the body 221A. The body 221A has a cylindrical shape, and an upper end thereof is increased in diameter. The insertion portion 223A has a cylindrical shape, and has a diameter smaller than a diameter of the body 221A. A male screw 224A is provided on an outer circumference of the insertion portion 223A. Although not illustrated, the electrodes 22B to 22D are also provided similarly as the electrode 22A.

The insertion portion 223A of the electrode 22A is inserted through the through hole 212A provided in the connecting portion 211A of the terminal 21A, and the male screw 224A protruding beyond a top surface 213A of the connecting portion 211A and the carbon nut 23A are screwed together, whereby the terminal 21A and an upper end of the electrode 22A are coupled to each other.

An electric resistance of the power supply portion 20A with the terminal 21A and the electrode 22A being coupled to each other increases or decreases depending on a contact resistance between the terminal 21A and the electrode 22A. For example, the top surface 222A of the electrode 22A may be in direct contact with a bottom surface 214A of the connecting portion 211A. In that case, the contact resistance increases as a contact area decreases due to surface roughness of the contact surface. In contrast, as illustrated in FIG. 6A, disposing a conductive sheet 24 between the top surface 222A of the electrode 22A and the bottom surface 214A of the connecting portion 211A increases the contact area because the conductive sheet 24 is in close contact with the bottom surface 214A and the top surface 222A. Thus, the contact resistance between the terminal 21A and the electrode 22A is lower than a case where the conductive sheet 24 is not disposed. As illustrated in FIG. 6B, the conductive sheet 24 is a disk-shaped sheet material having a hole into which the insertion portion 223A is to be inserted. The conductive sheet 24 is formed from, for example, a carbon-based fiber material.

Note that another conductive sheet 24 may also be disposed between the top surface 213A of the connecting portion 211A and the nut 23A in addition to between the bottom surface 214A of the connecting portion 211A and the top surface 222A of the electrode 22A. When the conductive sheet 24 is disposed on either one of the bottom surface 214A side or the top surface 213A side of the connecting portion 211A, the conductive sheet 24 is preferably disposed between the bottom surface 214A of the connecting portion 211A and the top surface 222A of the electrode 22A as illustrated in FIG. 6A. This is because disposing the conductive sheet 24 between the electrode 22A coupled to the power source and the terminal 21A integrally provided with the heat generating portion 30 effectively decreases the contact resistance.

Connection structures between the electrodes 22B to 22D and the corresponding terminals 21B to 21D are similar to the connection structure between the electrode 22A and the terminal 21A. Note that the conductive sheet 24 is disposed when it is necessary to decrease the contact resistance between each of the electrodes 22B to 22D and the corresponding one of the terminals 21B to 21D, and is not disposed when it is not necessary to decrease the contact resistance.

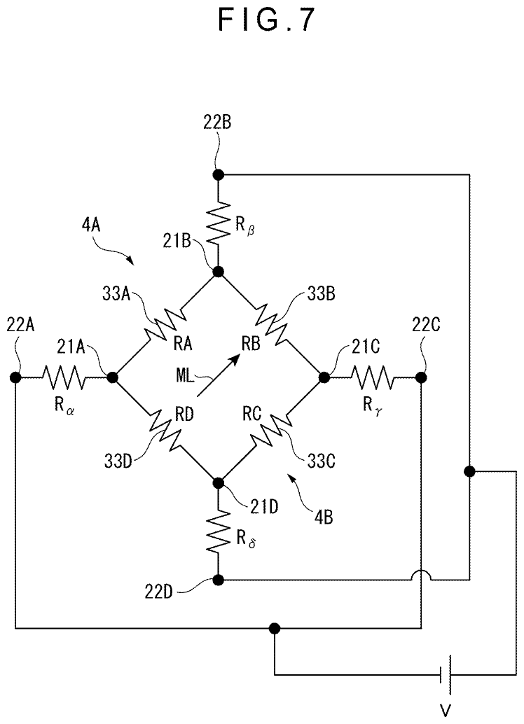

FIG. 7 is an equivalent circuit diagram of the heating device 4. In FIG. 7, V is a voltage value to be applied to the heating device 4. RA, RB, RC, and RD are resistance values of the first to fourth curve portions 33A to 33D, respectively. R_{α} is a contact resistance value between the terminal 21A and the electrode 22A. Similarly, R_{β} is a contact resistance value between the terminal 21B and the electrode 22B, R_{γ} is a contact resistance value between the terminal 21C and the electrode 22C, and R_{δ} is a contact resistance value between the terminal 21D and electrode 22D. In FIG. 7, the arrow ML indicates a horizontal-magnetic-field application direction.

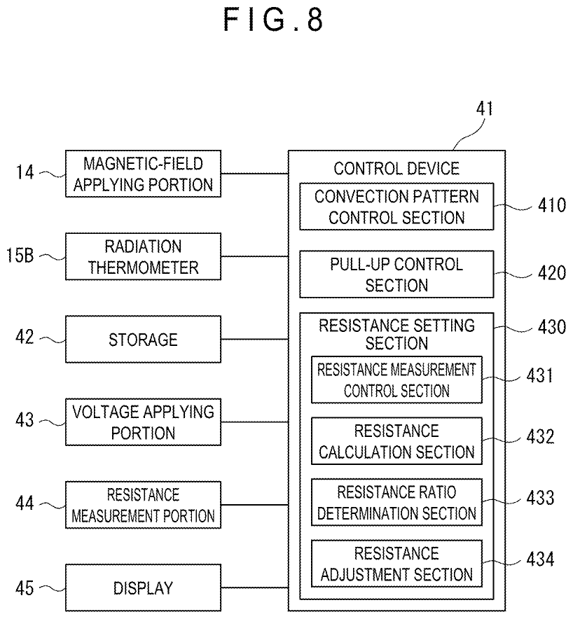

The heat generating portion 30, the terminals 21A to 21D, and the electrodes 22A to 22D are each formed from graphite. Graphite is generally less ductile. Thus, the contact resistance occurs in a contact portion between each of the terminals 21A to 21D and the corresponding one of the electrodes 22A to 22D. In FIG. 7, the resistance values of the electrodes 22A to 22D are ignored. This is because the electrodes 22A to 22D are generally short, and a current-carrying cable having an extremely low resistance value is used between each of the electrodes 22A to 22D and a voltage applying portion 43 (see FIG. 8) to be described later.

Making resistance distribution of the power supply portions 20A to 20D non-uniform controls a convection behavior of the silicon melt in a magnetic-field applying process, making it possible to grow high-quality monocrystalline silicon with less variation in oxygen concentration. In other words, the resistances of the heat generating portion 30, i.e., the respective element portions of the graphite heater, depend largely on processing accuracy (a thickness or a length) of the heater, and variation in resistance is less than or equal to 1%. Further, the resistances RA, RB, RC, and RD of the heat generating portion 30 are considerably larger than the contact resistances R_{α}, R_{β}, R_{γ}, and R_{δ} of the power supply portions 20A to 20D. Thus, values of current flowing through the resistances RA, RB, RC, and RD of the heat generating portion 30 hardly change even if the contact resistances R_{α}, R_{β}, R_{γ}, and R_{δ} are set to be non-uniform. Accordingly, heat generation distribution of the heat generating portion 30 is almost the same in the first heating region 4A and the second heating region 4B, and an effect on the convection behavior of the silicon melt is negligible.

It is therefore possible to: make the heat generation distribution imbalanced in the first heating region 4A and the second heating region 4B by the contact resistances R_{α}, R_{β}, R_{γ}, and R_{δ}, by making the resistance distribution of the power supply portions 20A to 20D, more specifically, a first resistance value R1 and a second resistance value R2, non-uniform; and fix the heat generation distribution of the graphite heater, i.e., the direction of the convection of the silicon melt. The first resistance value R1 is a sum of the contact resistances R_{α} and R_{β} of the first power supply portion (the power supply portions 20A and 20B) disposed in the first heating region 4A. The second resistance value R2 is a sum of the contact resistances R_{γ} and R_{δ} of the second power supply portion (the power supply portions 20C and 20D) disposed in the second heating region 4B. For example, when the first resistance value R1 is greater than the second resistance value R2, a heat generation amount in the first heating region 4A is greater than that in the second heating region 4B. In this case, the left side of the crucible 3 in FIG. 1 is more heated and an upward flow on the left side is dominant. This makes the convection flow of the silicon melt turn clockwise with respect to the horizontal-magnetic-field application direction, forming a clockwise vortex. When the second resistance value R2 is greater than the first resistance value R1, the upward flow on the right side of the crucible 3 in FIG. 1 is dominant, and a counterclockwise vortex is formed.

In other words, since the heat generation distribution of the heat generating portion 30 is almost the same in the first heating region 4A and the second heating region 4B, controlling magnitudes of the first resistance value R1 and the second resistance value R2 of the power supply portions makes it possible to control the imbalance of the heat generation distribution and to control a target vortex direction.

Further, an environment in the chamber 2 constantly changes due to aging deterioration of the carbon member being used, for example, and the contact resistances R_{α}, R_{β}, R_{γ}, and R_{δ} in the heating device 4 also change due to aging deterioration of the terminals 21A to 21D and the electrodes 22A to 22D, for example. When the contact resistances R_{α}, R_{β}, R_{γ}, and R_{δ} change, the heat generation distribution in the first heating region 4A and the second heating region 4B also changes. This affects stability of the direction of the convection of the silicon melt, resulting in variation in oxygen concentration. Thus, in the exemplary embodiment, the contact resistance is measured every time the monocrystalline silicon is pulled a predetermined number of times and the contact resistance is adjusted when a change occurs that can affect the direction of the convection of the silicon melt. This makes it possible to fix the direction of the vortex even when the monocrystalline silicon is repeatedly pulled, as will be described later.

As a result, batch-to-batch variation in amount of oxygen to be supplied from the quartz crucible 3B to the crystal-growth interface is reduced, resulting in the monocrystalline silicon having a stable oxygen concentration. It is possible to grow a crystal having a desired oxygen concentration along a growth axis of the crystal, and a yield of the crystal is thus improved.

In the exemplary embodiment, a resistance ratio is adjusted to be greater than or equal to a determination value set in advance, specifically greater than or equal to 1.2. The resistance ratio is a value obtained by dividing a higher resistance value by a lower resistance value out of the first resistance value R1 and the second resistance value R2.

For example, roughening the contact surface between the connecting portion 211A and the electrode 22A and the contact surface between the connecting portion 211B and the electrode 22B with use of mechanical polishing increases the first resistance value R1 that is the sum (R_{α}+R_{β}) of the respective contact resistances of the power supply portions 20A and 20B. In contrast, interposing the conductive sheet 24 between respective surfaces of the connecting portion 211C and the electrode 22C that are in contact with each other and the conductive sheet 24 between respective surfaces of the connecting portion 211D and the electrode 22D that are in contact with each other decreases the second resistance value R2 that is the sum (R_{γ}+R_{δ}) of the respective contact resistances of the power supply portions 20C and 20D. Accordingly, if R1>R2, adjustment may be performed to increase the first resistance value R1 or decrease the second resistance value R2 so that R1/R2>1.2 is satisfied. If R1<R2, adjustment may be performed to decrease the first resistance value R1 or increase the second resistance value R2 so that R2/R1>1.2 is satisfied.

As illustrated in FIG. 8, the monocrystalline silicon manufacturing apparatus 1 includes a control device 41, the magnetic-field applying portion 14, the radiation thermometer 15B, a storage 42, the voltage applying portion 43, a resistance measurement portion 44, and a display 45.

The storage 42 stores, for example, rules for setting, based on measurement values of the contact resistances R_{α}, R_{β}, R_{γ}, and R_{δ}, pull-up conditions to make the oxygen concentration of the monocrystalline silicon SM a desired value and adjustment rules of the contact resistances R_{α}, R_{β}, R_{γ}, and R_{δ}. The pull-up conditions include, for example, a flow rate of the inert gas, an in-furnace pressure of the chamber 2, and a rotation speed of the crucible 3. The adjustment rules of the contact resistances R_{α}, R_{β}, R_{γ}, and R_{δ} include, for example, a selection of the power supply portions 20A to 20D to be adjusted and a selection of an adjustment method such as the disposition of the conductive sheet 24 or the mechanical polishing of the contact surface.

The voltage applying portion 43 is controlled by the control device 41 and applies a predetermined voltage to the heating device 4.

The resistance measurement portion 44 measures resistance values of the heating device 4. The resistance measurement portion 44 includes, for example, a resistance meter that measures a resistance by a four terminal method. The resistance measurement portion 44 measures a resistance value when an operator brings a probe into contact with a measurement location of the heating device 4, and outputs measurement data to the control device 41. Note that a measurement value may be inputted by the operator using an input device such as a keyboard or a touch panel provided on the control device 41.

The display 45 includes, for example, a liquid crystal display. A variety of information and operation instructions is displayed on the display 45 for the operator.

The control device 41 includes a convection pattern control section 410, a pull-up control section 420, and a resistance setting section 430.

The convection pattern control section 410 controls the voltage applying portion 43 to heat the silicon melt M using the heating device 4, and controls the magnetic-field applying portion 14 to apply the horizontal magnetic field to the silicon melt M, thereby fixing the direction of the convection in a cross section orthogonal to the magnetic field.

The pull-up control section 420 performs control to pull up the monocrystalline silicon SM after the convection pattern control section 410 fixes the convection direction.

The resistance setting section 430 includes a resistance measurement control section 431, a resistance calculation section 432, a resistance ratio determination section 433, and a resistance adjustment section 434.

The resistance measurement control section 431 uses the resistance measurement portion 44 to measure the resistance values of the heating device 4.

The resistance calculation section 432 calculates the contact resistances R_{α}, R_{β}, R_{γ}, and R_{δ} using the measurement data of the respective resistance values, and calculates the first resistance value R1 and the second resistance value R2 using the contact resistances R_{α}, R_{β}, R_{γ}, and R_{δ}.

The resistance ratio determination section 433 calculates the resistance ratio between the first resistance value R1 and the second resistance value R2, and determines whether the resistance ratio is greater than or equal to the determination value.

When the resistance ratio determination section 433 determines that the resistance ratio is greater than or equal to the determination value, the resistance adjustment section 434 displays on the display 45 that adjusting the contact resistance is unnecessary. When the resistance ratio determination section 433 determines that the resistance ratio is less than the determination value, the resistance adjustment section 434 selects a target for adjusting the contact resistance from among the power supply portions 20A to 20D and determines the adjustment method, based on the contact resistance values R_{α}, R_{β}, R_{γ}, and R_{δ} calculated by the resistance measurement control section 431 and the adjustment rules stored in the storage 42, and displays an operation instruction for the adjustment on the display 45.

### Method of Manufacturing Monocrystalline Silicon

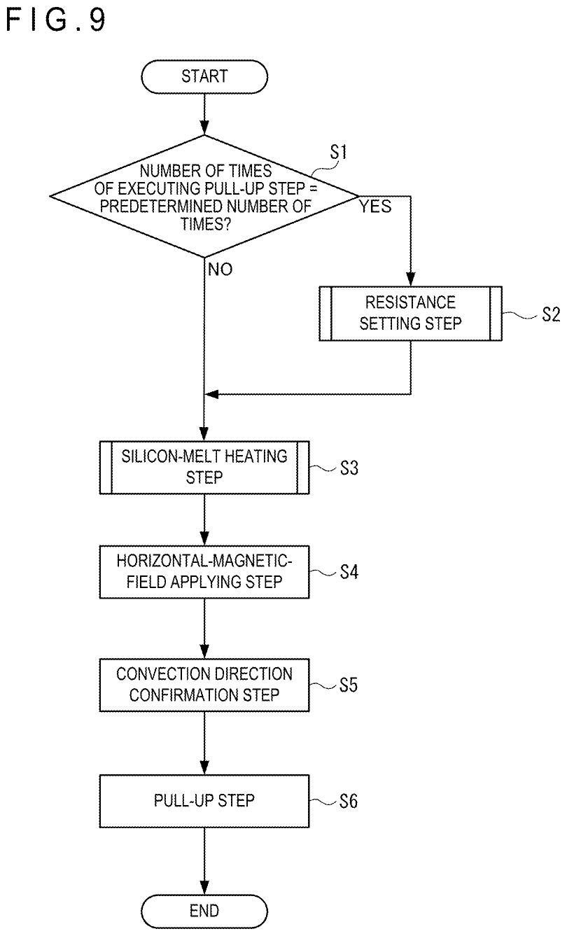

Next, the method of manufacturing the monocrystalline silicon according to the exemplary embodiment is described referring to flowcharts illustrated in FIGS. 9 to 13.

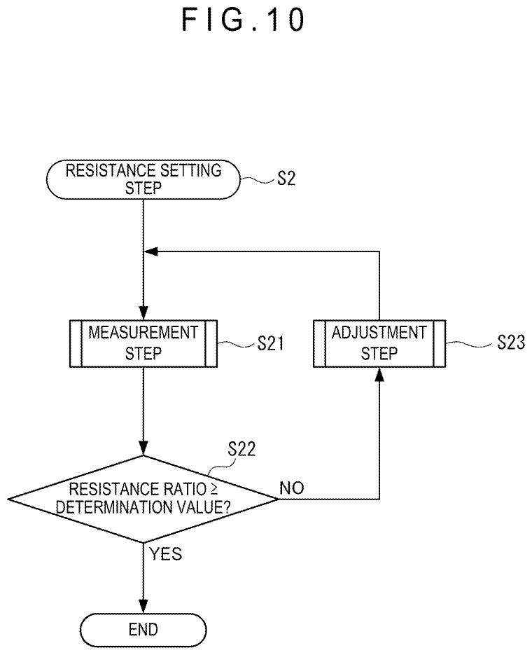

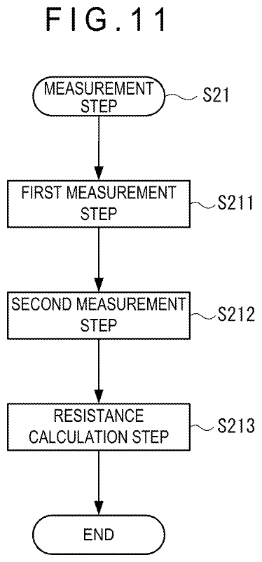

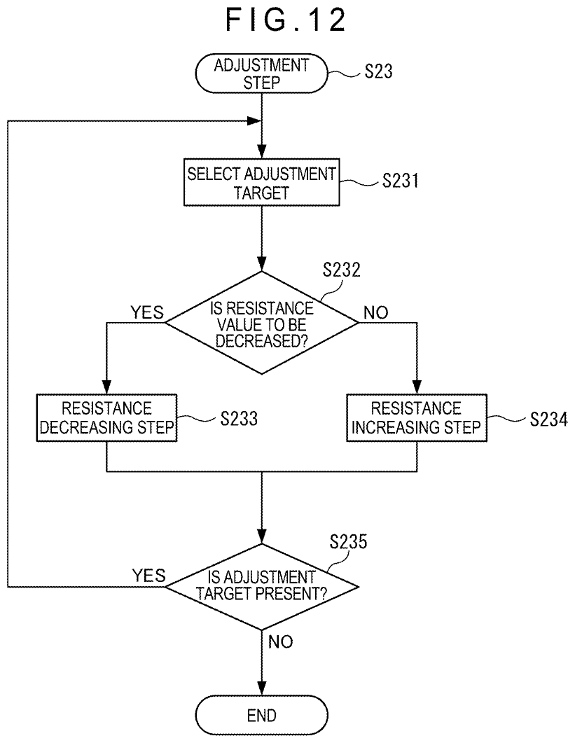

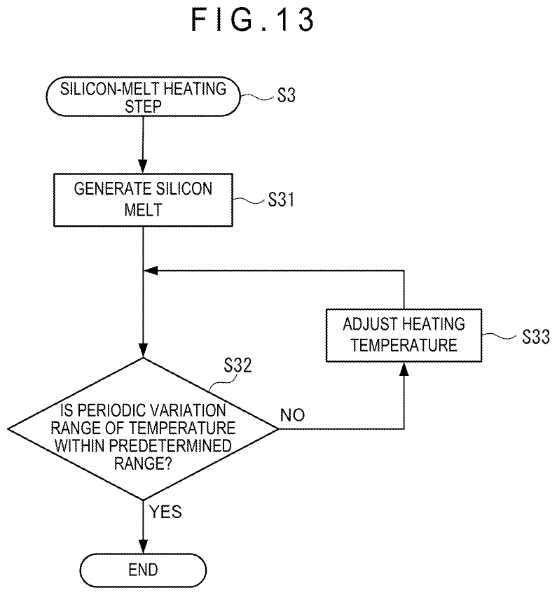

FIG. 9 is a flowchart illustrating one batch process for manufacturing one piece of monocrystalline silicon. FIG. 10 is a flowchart illustrating a resistance setting step illustrated in FIG. 9. FIG. 11 is a flowchart illustrating a measurement step illustrated in FIG. 10. FIG. 12 is a flowchart illustrating an adjustment step illustrated in FIG. 10. FIG. 13 is a flowchart illustrating a silicon-melt heating step illustrated in FIG. 9.

Prior to executing the flowchart of FIG. 9, the pull-up conditions (for example, the flow rate of the inert gas, the in-furnace pressure of the chamber 2, and the rotation speed of the crucible 3) to make the oxygen concentration of the monocrystalline silicon SM a desired value are determined in advance as pre-decided conditions and stored in storage 42. The oxygen concentration of the pre-decided conditions may be values of oxygen concentration at multiple points in a longitudinal direction of a straight body that configures the monocrystalline silicon SM, or may be an average of the values of the oxygen concentration at the multiple points.

Further, the predetermined number of times that is an execution interval of the resistance setting step is stored in the storage 42. The predetermined number of times sets a timing at which a process of setting the resistance value of the contact resistance of each of the power supply portions 20A to 20D is executed. It is possible to set the predetermined number of times, for example, by experimentally obtaining the number of times that the resistance ratio between the first resistance value R1 and the second resistance value R2 changes to less than the determination value due to the aging deterioration of the carbon members such as the terminals 21A to 21D or the electrodes 22A to 22D. In the exemplary embodiment, the predetermined number of times is set within a range from 1 to 50 times.

When the control device 41 starts a monocrystalline-silicon manufacturing step, the control device 41 first determines, as illustrated in FIG. 9, whether the number of times of executing a pull-up step is the predetermined number of times (Step S1). When the predetermined number of times is 30, the control device 41 determines YES in Step S1 every time the pull-up step is executed 30 times.

When the control device 41 determines YES in Step S1, the control device 41 executes the resistance setting step (Step S2). Note that the resistance setting step S2 is also executed at a time of installing the monocrystalline silicon manufacturing apparatus 1 or maintaining the heating device 4, for example.

When starting the resistance setting step S2, as illustrated in FIG. 10, the control device 41 causes the resistance measurement control section 431 of the resistance setting section 430 to execute a measurement step of measuring a resistance value (Step S21). When executing the measurement step S21, as illustrated in FIG. 11, the resistance measurement control section 431 executes a first measurement step of measuring a combined resistance of the heat generating portion 30 and the power supply portions 20A to 20D (Step S211). In the first measurement step, the resistance measurement portion 44 measures a combined resistance between the electrode 22A and the electrode 22B. In this case, the operator measures the combined resistance between the electrode 22A and the electrode 22B by bringing a probe of the resistance measurement portion 44 into contact with a position at which the combined resistance between the electrode 22A and the electrode 22B is measurable, for example, a metallic terminal that couples the electrodes 22A and 22B to the current-carrying cable.

By performing a similar operation, the resistance measurement portion 44 sequentially measures a combined resistance between the electrode 22B and the electrode 22C, a combined resistance between the electrode 22C and the electrode 22D, and a combined resistance between the electrode 22D and the electrode 22A.

Thereafter, the resistance measurement control section 431 executes a second measurement step of measuring a combined resistance of the heat generating portion 30 (Step S212). In the second measurement step, the resistance measurement portion 44 measures a combined resistance between the terminal 21A and the terminal 21B. Similarly, the resistance measurement portion 44 sequentially measures a combined resistance between the terminal 21B and the terminal 21C, a combined resistance between the terminal 21C and the terminal 21D, and a combined resistance between the terminal 21D and the terminal 21A. In this case, the operator measures the combined resistance by bringing the probe of resistance measurement portion 44 into contact with a position in the same plane and at the same height in each of the terminals 21A to 21D. This is because the combined resistance to be measured varies depending on the position with which the probe is brought into contact.

As described above, the resistance measurement portion 44 measures each resistance value illustrated in FIG. 7, and the measurement data thereof is inputted to the control device 41.

Thereafter, as illustrated in FIG. 11, the resistance calculation section 432 calculates the contact resistances R_{α}, R_{β}, R_{γ}, and R_{δ} based on the data of the measured combined resistances, and executes a resistance calculation step of calculating the first resistance value R1 and the second resistance value R2 (Step S213). In other words, the resistance calculation section 432 calculates the contact resistances R_{α}, R_{β}, R_{γ}, and R_{δ} using simultaneous equations with eight variables set based on the circuit diagram of FIG. 7 and the eight resistance values measured in the first measurement step S211 and the second measurement step S212. Thereafter, the resistance calculation section 432 calculates the first resistance value R1=R_{α}+R_{β} and the second resistance value R2=R_{γ}+R_{δ}. Then, the measurement step S21 ends.

Thereafter, as illustrated in FIG. 10, when the measurement step S21 ends, the resistance ratio determination section 433 of the resistance setting section 430 determines whether the resistance ratio calculated based on the first resistance value R1 and the second resistance value R2 calculated in the resistance calculation step S213 is greater than or equal to the determination value (Step S22). The resistance ratio is calculated by dividing the higher resistance value by the lower resistance value. The resistance ratio is calculated by R1/R2 if R1≥R2, and is calculated by R2/R1 if R1<R2.

Note that the determination value is stored in the storage 42 of the monocrystalline silicon manufacturing apparatus 1. For example, experiments on whether the convection direction of the silicon melt is fixed are performed in the monocrystalline silicon manufacturing apparatus 1 by setting the resistance ratio to different values, and a value of the resistance ratio at which the convection direction of the silicon melt is fixed is set as the determination value. In the exemplary embodiment, the determination value is set to “1.2”.

When the control device 41 determines NO in Step S22, the resistance adjustment section 434 executes an adjustment step of adjusting the resistance value (Step S23).

When executing the adjustment step S23, as illustrated in FIG. 12, the resistance adjustment section 434 selects an adjustment target to be decreased in the contact resistance by disposing the conductive sheet 24 or to be increased in the contact resistance by roughening the surface with use of the mechanical polishing based on the contact resistances R_{α}, R_{β}, R_{γ}, and R_{δ} of the four power supply portions 20A to 20D and the adjustment rules stored in the storage 42 (Step S231).

Thereafter, the resistance adjustment section 434 determines whether the selected adjustment target is a target to be decreased in resistance value (Step S232).

When the resistance adjustment section 434 determines YES in Step S232, the resistance adjustment section 434 executes a resistance decreasing step (Step S233). In the resistance decreasing step S233, the resistance adjustment section 434 displays, on the display 45, the operation instruction to provide the conductive sheet 24 for the power supply portion selected as the target to be decreased in the resistance value out of the power supply portions 20A to 20D. The operator disposes the conductive sheet 24 between the terminal and the electrode of the selected power supply portion to decrease the contact resistance in accordance with the operation instruction.

When the resistance adjustment section 434 determines NO in Step S232, the resistance adjustment section 434 executes a resistance increasing step (Step S234). In the resistance increasing step S234, the resistance adjustment section 434 displays, on the display 45, the operation instruction to roughen the surface with use of the mechanical polishing for the power supply portion selected as the target to be increased in the resistance value out of the power supply portions 20A to 20D. The operator performs the mechanical polishing on the contact surface between the terminal and the electrode of the selected power supply portion to increase the contact resistance in accordance with the operation instruction.

After executing Step S233 or S234, the resistance adjustment section 434 determines whether another power supply portion to be adjusted is present (Step S235). When the resistance adjustment section 434 determines YES in Step S235, the process returns to Step S231, and Steps S231 to S235 are executed again. When the resistance adjustment section 434 determines NO in Step S235, the adjustment step S23 ends.

The adjustment rules used by resistance adjustment section 434 are set so that the resistance decreasing step S233 of disposing the conductive sheet 24 is executed in preference to the resistance increasing step S234. This is because the disposing the conductive sheet 24 is easier than the performing the mechanical polishing. The resistance adjustment section 434 thus issues the operation instruction to preferentially decrease the contact resistance of the smaller resistance value when the resistance ratio between the first resistance value R1 and the second resistance value R2 is less than the determination value.

For example, if R1>R2 and R1/R2<1.2, the resistance adjustment section 434 may determine that it is possible to make the resistance ratio greater than or equal to the determination value by decreasing only one of the resistances in the second resistance value R2, i.e., the contact resistance R_{γ} or the contact resistance R_{δ}. In this case, the resistance adjustment section 434 issues the operation instruction to decrease the resistance value by providing the conductive sheet 24 for the power supply portion 20C or the power supply portion 20D of which resistance value (the contact resistance R_{γ} or R_{δ}) is higher. Further, when the resistance adjustment section 434 determines that it is possible to make the resistance ratio greater than or equal to the determination value by decreasing both the contact resistances R_{γ} and R_{δ}, the resistance adjustment section 434 issues the operation instruction to decrease the resistance value by providing the conductive sheet 24 for each of the power supply portions 20C and 20D. Note that the storage 42 stores an amount of change in contact resistance before and after disposing the conductive sheet 24 based on previous experimental data. For example, when the contact resistance is relatively high, it is highly possible that the contact surface is roughened and the contact area between the terminal and the electrode is small. The amount of decrease in resistance value when the conductive sheet 24 is disposed is therefore relatively large. In contrast, when the contact resistance is relatively low, it is highly possible that the contact area between the terminal and the electrode is large, and the amount of decrease in resistance value when the conductive sheet 24 is disposed is smaller than that when the contact resistance is high. Thus, the resistance adjustment section 434 can estimate the amount of decrease of the case where the conductive sheet 24 is disposed based on the measured contact resistance value, and determine whether to dispose the conductive sheet 24 in only one of the power supply portions or in each of the power supply portions based on the estimation.

Furthermore, when the resistance adjustment section 434 determines that it is not possible to make the resistance ratio greater than or equal to the determination value by simply decreasing the second resistance value R2, i.e., the contact resistances R_{γ} and R_{δ}, the resistance adjustment section 434 issues the operation instruction to increase the first resistance value R1 in addition to the operation of decreasing the second resistance value R2. Here, when the resistance adjustment section 434 determines that it is possible to make the resistance ratio greater than or equal to the determination value by increasing only one of the resistances in the first resistance value R1, i.e., the contact resistance R_{α} or the contact resistance R_{β}, the resistance adjustment section 434 issues the operation instruction to increase the resistance value by performing the mechanical polishing for the power supply portion 20A or the power supply portion 20B of which resistance value (the contact resistance R_{α} or R_{β}) is lower. Moreover, when the resistance adjustment section 434 determines that it is possible to make the resistance ratio greater than or equal to the determination value by increasing both the contact resistances R_{α} and R_{β}, the resistance adjustment section 434 issues the operation instruction to increase the resistance value by performing the mechanical polishing for each of the power supply portions 20A and 20B.

The operator adjusts the contact resistances of the power supply portions 20A to 20D based on the operation instruction from the resistance adjustment section 434 displayed on the display 45. When the adjustment is completed, the operator inputs the completion of the adjustment to the control device 41.

When Step S23 ends, as illustrated in FIG. 10, the control device 41 executes the measurement step S21 and the determination step S22 again, and determines again whether the resistance ratio is greater than or equal to the determination value.

When the control device 41 determines NO in Step S22, the adjustment step S23, the measurement step S21, and the determination step S22 are repeated until the control device 41 determines YES in the determination step of Step S22.

When the control device 41 determines YES in Step S22, the control device 41 determines that the contact resistances of the power supply portions 20A to 20D are appropriately adjusted. The resistance setting step of Step S2 ends, and the process returns to the process of FIG. 9.

As illustrated in FIG. 9, when the control device 41 determines NO in Step S1, that is, when it is not a timing at which the resistance value is to be set, or when the resistance setting step of Step S2 ends, the convection pattern control section 410 executes the silicon-melt heating step (Step S3).

In the silicon-melt heating step S3, as illustrated in FIG. 13, the convection pattern control section 410 maintains an inside of the chamber 2 in a reduced pressure inert gas atmosphere in a magnetic-field-free state, rotates the crucible 3, and causes the voltage applying portion 43 to operate the heating device 4 to melt a solid raw material such as polycrystalline silicon with which the crucible 3 is filled to generate the silicon melt M (Step S31).

At this time, the convection pattern control section 410 causes the voltage applying portion 43 to apply the same magnitude of voltage to the first heating region 4A and the second heating region 4B. Here, when the first resistance value R1 is 1.2 times or more of the second resistance value R2, a temperature of the first power supply portion (the power supply portions 20A and 20B) is higher than that of the second power supply portion (the power supply portions 20C and 20D) due to Joule heat generation, and the left side (the first heating region 4A side) of the silicon melt M is heated at a higher temperature than a temperature of the right side (the second heating region 4B side). The convection pattern control section 410 controls the heating so that the temperature of the silicon melt M is in a range from 1,415 degrees C. to 1,500 degrees C.

The convection occurs in the silicon melt M generated in Step S31 under effects of heat and rotation of the crucible 3. The convection pattern control section 410 thus determines whether the vortex of the silicon melt M is rotating periodically. Specifically, the convection pattern control section 410 confirms temporal change (temperature transition) of the temperature at the first measurement point P1 or the second measurement point P2 measured by the temperature sensor 15, and determines whether a periodic variation range that is a variation range of a maximum value and a minimum value of measurement temperature that periodically varies is within a predetermined temperature range (a predetermined range) (Step S32).

The process of Step S32 makes it possible to determine the stability, i.e., whether the vortex of the silicon melt M is rotating periodically.

When the convection pattern control section 410 determines in Step S32 that the periodic variation range is not within the predetermined range, that is, the vortex is not rotating periodically, the convection pattern control section 410 adjusts heating temperature of the silicon melt M (Step S33), and performs Step S32 after an elapse of a predetermined period of time.

When the convection pattern control section 410 determines in Step S32 that the periodic variation range is within the predetermined range and the vortex is periodically and stably rotating, the step of adjusting a heating condition of the silicon melt of Step S3 ends. Note that the convection pattern control section 410 continues to heat the silicon melt by the voltage applying portion 43 after completion of Step S3.

After Step S3 ends, as illustrated in FIG. 9, the control device 41 executes a horizontal-magnetic-field applying step (Step S4) of causing the convection pattern control section 410 to control the magnetic-field applying portion 14 to apply the horizontal magnetic field of greater than or equal to 0.2 Tesla and less than or equal to 0.6 Tesla to silicon melt M. The process of Step S4 fixes the convection direction of the silicon melt M.

Thereafter, the convection pattern control section 410 executes a convection direction confirmation step (Step S5) of confirming a temperature difference between the first measurement point P1 and the second measurement point P2 measured by the temperature sensor 15, and confirming whether the convection direction is clockwise or counterclockwise.

Then, the pull-up control section 420 executes the pull-up step (Step S6) in which the seed crystal SC is brought into contact with the silicon melt M in a state where the horizontal magnetic field of greater than or equal to 0.2 Tesla and less than or equal to 0.6 Tesla is maintained based on the predetermined conditions and then the monocrystalline silicon SM having the straight body with a desired oxygen concentration is pulled up.

Note that the process of confirming the periodic variation range in Step S32, the process of adjusting the heating temperature in Step S33, the process of starting the application of the horizontal magnetic field in Step S4, the process of confirming the convection direction by the temperature measurement in Step S5, and the pull-up process in Step S6 may each be performed by an operation of the operator.

The straight body included in the monocrystalline silicon SM pulled up using the method of manufacturing the monocrystalline silicon described above is cut into a silicon wafer by, for example, a wire saw. Thereafter, the cut silicon wafer is subjected to a lapping step and a polishing step to thereby obtain the silicon wafer. Such a process corresponds to a method of manufacturing a silicon wafer according to the invention.

### Action and Effects of Exemplary Embodiment

According to the exemplary embodiment, every time the pull-up step S6 is executed a predetermined number of times, the resistance setting step of Step S2 is executed to set the resistance ratio between the first resistance value R1 and the second resistance value R2 to be greater than or equal to 1.2 that is the determination value. The first resistance value R1 is the sum of the contact resistances R_{α} and R_{β} of the power supply portions 20A and 20B disposed in the first heating region 4A, and the second resistance value R2 is the sum of the contact resistances R_{γ} and R_{δ} of the power supply portions 20C and 20D disposed in the second heating region 4B. This makes it possible to make the heat generation amount of the power supply portions 20A and 20B in the first heating region 4A greater than the heat generation amount of the power supply portions 20C and 20D in the second heating region 4B.

It is therefore possible to easily fix the direction of the convection of the silicon melt M in one direction in the cross section orthogonal to the magnetic field regardless of structural symmetry of the monocrystalline silicon manufacturing apparatus 1. Fixing the convection of the silicon melt M in one direction inhibits the variation in oxygen concentration for each piece of monocrystalline silicon SM. As a result, it is possible to inhibit furnace-to-furnace or batch-to-batch variation in the quality and productivity of the monocrystalline silicon.

Specifically, the contact resistances between the electrodes 22A to 22D and the terminals 21A to 21D included in the respective power supply portions 20A to 20D are each decreased by interposing the conductive sheet 24 between the relevant terminal and the corresponding one of the electrodes, or increased by roughening the contact surface with use of the mechanical polishing, whereby the resistance ratio between the first resistance value R1 and the second resistance value R2 is set to be greater than or equal to the determination value. With such simple measures, the variation in oxygen concentration for each piece of monocrystalline silicon SM can be inhibited.

According to the exemplary embodiment, the resistance setting step of Step S2 is executed every time the pull-up step S6 is executed a predetermined number of times. This makes it possible to regularly measure and adjust the contact resistance of each of the power supply portions 20A to 20D, and to fix the direction of the convection of the silicon melt M, even when the terminals 21A to 21D or the electrodes 22A to 22D deteriorate with time. This improves the yield of the monocrystalline silicon.

Further, the predetermined number of times, which is an execution interval of the resistance setting step, is set to be greater than or equal 1 and less than or equal to 50, making it possible to adjust the contact resistance at appropriate intervals depending on the monocrystalline silicon manufacturing apparatus 1. For example, when the predetermined number of times is set to 1, the contact resistance is measured every time the monocrystalline silicon SM is pulled up, the contact resistance can be adjusted at that time if necessary. This reliably fixes the direction of the convection of the silicon melt M, thus improving the yield of the monocrystalline silicon. Further, when the predetermined number of times is set to 50, for example, the contact resistance can be measured and adjusted in accordance with a timing at which a component having a short lifetime is replaced in the monocrystalline silicon manufacturing apparatus 1. This improves the yield of the monocrystalline silicon without decreasing manufacturing efficiency of the monocrystalline silicon. Note that, an actual predetermined number of times may be a most appropriate number of times that is obtained by an experiment depending on, for example, a kind of the crystal and a configuration of the monocrystalline silicon manufacturing apparatus 1 such as a shape of a hot zone.

According to the exemplary embodiment, the contact resistances between the terminals 21A to 21D and the electrodes 22A to 22D are adjusted, so that the heating device 4 needs no special processing. A commercially available product is thus usable and cost is reducible. Further, the heating device 4 having a symmetrical shape and a uniform thickness is usable. Such a device has a simple structure with high durability.

According to the exemplary embodiment, the control device 41 measures the first resistance value R1 and the second resistance value R2 in the resistance setting step of Step S2, and when the resistance ratio therebetween is greater than or equal to the determination value, proposes the target whose resistance value is to be adjusted and the adjustment method based on the measured contact resistance. The operator can thus easily and quickly adjust the resistance value.

Further, in the measurement step S21, the combined resistance of the heat generating portion 30 and the power supply portions 20A to 20D is measured in the first measurement step S211, and the combined resistance of the heat generating portion 30 is measured in the second measurement step S212. This makes it possible to measure a correct contact resistance without disassembling the heating device 4. Furthermore, the resistance measurement portion 44 includes the resistance meter that measures the resistance by the four terminal method. This makes it possible to accurately measure each combined resistance, and to accurately obtain the contact resistance that is calculated based on the measured value.

### Modifications

Although the exemplary embodiment of the invention has been described with reference to the drawings, a specific configuration is not limited to the exemplary embodiment, and various improvements and changes in designs that do not depart from the gist of the invention are included in the invention.

For example, the predetermined number of times of the pull-up step by which the execution interval of the resistance setting step is set is not limited to greater than or equal to 1 and less than or equal to 50. For example, it is assumed that an experiment is carried out regarding the number of times of executing the pull-up step to decrease the resistance ratio between the first resistance value R1 and the second resistance value R2 in the monocrystalline silicon manufacturing apparatus 1 to less than the determination value. When the resistance ratio decreases to less than the determination value by, for example, an average of 60 times, the predetermined number of times may be set to 60 times. That is, the predetermined number of times may be set by actually carrying out an experiment depending on, for example, a type of the monocrystalline silicon manufacturing apparatus 1 used for manufacturing the monocrystalline silicon.

Further, the timing at which the resistance setting step is executed is not limited to every time the pull-up step is executed the predetermined number of times. The resistance setting step may be executed when a parameter based on which a change in the resistance ratio is estimatable corresponds to a condition. For example, when it is found a correlation between the resistance ratio and a time period from start of heating by the heating device 4 until the temperature at the first measurement point P1 and the temperature at the second measurement point P2 measured by the radiation thermometer 15B reach the respective predetermined temperatures, the resistance setting step may be executed when the time period until reaching the predetermined temperatures corresponds to a predetermined condition.

The determination value based on which the resistance ratio is to be determined is not limited to “1.2”, and may be set to a value obtained by an experiment. For example, when the resistance ratio at which the direction of the convection of the silicon melt M is fixed is “1.25”, the determination value may also be set to “1.25”. That is, the resistance ratio at which the direction of the convection of the silicon melt M is fixed depends on other factors that affect the heat generation distribution in the first heating region 4A and the second heating region 4B, such as the kind of the monocrystalline silicon manufactured by the monocrystalline silicon manufacturing apparatus 1, the shape of the hot zone, or the configuration of the heat generating portion 30. Thus, the resistance ratio is preferably experimentally obtained in each monocrystalline silicon manufacturing apparatus 1, and may be set based on the experimental data. Further, when it is possible to simulate the heat generation distribution of the heating device 4 and the convection of the silicon melt M, the determination value may be set based on the simulation result without conducting the experiment.

Furthermore, the determination value based on which the resistance ratio is to be determined may be set to a value greater than or equal to the value obtained by the experiment or the simulation. For example, when the experimentally obtained value is “1.2”, the determination value may be set to a larger value of “1.2 or more”. Setting the determination value to a larger value makes it possible to increase a difference between the heat generation amounts in the respective heating regions 4A and 4B, and to further stabilize the direction of the convection of the silicon melt M.

The determination value based on which the resistance ratio is to be determined may be changed based on the number of times the pull-up step of the monocrystalline silicon is executed. For example, it is assumed that the resistance setting step is executed every 10 times the pull-up step is executed. In this case, the determination value based on when the pull-up step is executed 10 times may be set to “1.2”, the determination value based on when the pull-up step is executed 20 times may be set to “1.22”, the determination value when the pull-up step is executed 30 times may be set to “1.24”, and so on. The determination value may thus be changed depending on the number of times the pull-up step is executed. Such changing of the determination value is effective, for example, in a case where a thermal environment in the hot zone of the monocrystalline silicon manufacturing apparatus 1 is affected by the aging deterioration of the components and the like and the direction of the convection of the silicon melt M cannot be fixed unless further increasing the resistance ratio between the first resistance value R1 and the second resistance value R2.

In the exemplary embodiment described above, the power supply portions 20A to 20D are disposed at the respective positions that are line-symmetric with respect to the imaginary line VL; however, the present invention is not limited thereto. That is, in the above exemplary embodiment, a tolerance angle between the imaginary line VL and the line joining the center axis CA of the heating device 4 and each of the power supply portions 20A to 20D is set to 45 degrees; however, for example, the power supply portions 20A to 20D may be disposed in such a manner that the tolerance angle between the imaginary line VL and the line joining the center axis CA and each of the power supply portions 20A and 20C is set to 30 degrees, and the tolerance angle between the imaginary line VL and the line joining the center axis CA and each of the power supply portions 20B and 20D is set to 60 degrees. That is, it is only necessary to dispose the power supply portions 20A to 20D at 90 degree intervals in the circumferential direction of the heat generating portion 30, dispose the power supply portions 20A and 20B serving as the first power supply portion in the first heating region 4A, and dispose the power supply portions 20C and 20D serving as the second power supply portion in the second heating region 4B, in order to make the heat generation distribution of the heat generating portion 30 uniform.

In the above exemplary embodiment, the conductive sheet 24 is disposed in the resistance decreasing step S233, and the surfaces of the terminals 21A to 21D and the electrodes 22A to 22D are roughened with use of the mechanical polishing in the resistance increasing step S234; however, the resistance value may be decreased or increased by other methods. For example, the resistance value may be adjusted by interposing an electrical resistance adjuster having a plate shape formed from, for example, a carbon-based fiber material between each of the terminals 21A to 21D and the corresponding one of the electrodes 22A to 22D and adjusting the number of the interposed electrical resistance adjusters. That is, making the total number of electrical resistance adjusters to be provided for the power supply portions 20A and 20B serving as the first power supply portion greater than the total number of electrical resistance adjusters to be provided for the power supply portions 20C and 20D serving as the second power supply portion causes the first resistance value R1 to be higher than the second resistance value R2, and changing the ratio between the total numbers also changes the resistance ratio between the first resistance value R1 and the second resistance value R2.

Further, the electrical resistance adjuster may be a thick disk-shaped sheet formed from porous carbon that is configured to purposefully increase the resistance, for example. The first resistance value R1 and the second resistance value R2 may be adjusted by changing a thickness dimension of the disk-shaped sheet to be provided for each of the power supply portions 20A and 20B and a thickness dimension of the disk-shaped sheet to be provided for each of the power supply portions 20C and 20D.

That is, the first resistance value R1 and the second resistance value R2 may be adjusted by changing, for example, the number of electrical resistance adjusters to be provided for the first power supply portion and the number of electrical resistance adjusters to be provided for the second power supply portion, or the thickness dimension of the electrical resistance adjuster to be provided for the first power supply portion and the thickness dimension of the electrical resistance adjuster to be provided for the second power supply portion to make the resistance values of the respective electrical resistance adjusters different from each other.

As a method of changing the first resistance value R1 and the second resistance value R2, for example, a method of adjusting tightening force of the nuts 23A to 23D to be used when the electrodes 22A to 22D are coupled to the terminals 21A to 21D is usable. For example, increasing the tightening force of the nuts 23A to 23D increases the contact areas between the terminals 21A to 21D and the electrodes 22A to 22D, which makes it possible to decrease the respective contact resistances. In this case, when the conductive sheets 24 are disposed and the tightening force of the nuts 23A to 23D is increased, the respective contact resistances can further decrease.

In contrast, decreasing the tightening force of the nuts 23A to 23D reduces the contact areas between the terminals 21A to 21D and the electrodes 22A to 22D, which makes it possible to increase the respective contact resistances. In this case, when the contact surfaces are roughened with use of the mechanical polishing and the tightening force of the nuts 23A to 23D is decreased, the respective contact resistances can further increase.

Further, the contact resistance may be changed by combining the adjustment of the tightening force of the nut and the adjustment by the disposition of the conductive sheet 24 or the mechanical polishing.

Although four power supply portions 20A to 20D are provided in the above exemplary embodiment, the number of power supply portions may be, for example, six or eight as long as the first heating region 4A and the second heating region 4B include the same number of power supply portions.

### EXAMPLES

Next, Examples of the invention will be described. It should be noted that the invention is by no means limited to Examples.

Seven monocrystalline silicon manufacturing apparatuses 1, from #1 to #7, according to the exemplary embodiment having the same in-furnace structure were prepared. The heating device 4 of each of the monocrystalline silicon manufacturing apparatuses 1 was thus represented by the equivalent circuit illustrated in FIG. 5, and had four power supply portions 20A to 20D. The contact resistances of the power supply portions 20A to 20D were measured by the resistance measurement portion 44 using a principle of the four terminal method.

Specifically, a constant current was passed between the electrode 22A and the electrode 22B, a voltage between the electrode 22A and the electrode 22B was measured, and a combined resistance between the electrode 22A and the electrode 22B was measured. In a similar manner, a combined resistance between the electrode 22B and the electrode 22C, a combined resistance between the electrode 22C and the electrode 22D, and a combined resistance between the electrode 22D and the electrode 22A were each measured.

Thereafter, a constant current was also passed between the electrode 22A and the electrode 22B, a voltage between the terminal 21A and the terminal 21B was measured, and a combined resistance between the terminal 21A and the terminal 21B was measured. In a similar manner, a combined resistance between the terminal 21B and the terminal 21C, a combined resistance between the terminal 21C and the terminal 21D, and a combined resistance between the terminal 21D and the terminal 21A were each measured.

The control device 41 solved the simultaneous equations set based on the equivalent circuit of FIG. 5 using the eight combined resistance values measured by the resistance measurement portion 44 to calculate the contact resistances R_{α}, R_{β}, R_{γ}, and R_{δ} of the four power supply portions 20A to 20D.

A heat generation amount W of each of the power supply portions 20A to 20D is related to the contact resistance R and a current I passing through the resistance, and is calculated by W=RI². The resistance distribution of the power supply portions 20A to 20D may thus be considered to be equivalent to the heat generation distribution of the power supply portions 20A to 20D. In contrast, the resistances of the heat generating portion 30 depend largely on the processing accuracy (a thickness and a length) of the heater, and the variation in resistance is less than or equal to 1%. The effect of the heat generation distribution of the heat generating portion 30 on the fixed behavior of the convection of the silicon melt is thus negligible. The resistance distribution of the power supply portions 20A to 20D thus determines the heat generation distribution of the heating device 4 used for growing crystals, and a fixed status of the direction of the convection of the silicon melt is determined based on the heat generation distribution.

Table 1 shows the contact resistances of the power supply portions 20A to 20D, the first resistance value R1, the second resistance value R2, the resistance ratio between the first resistance value R1 and the second resistance value R2, the direction of the convection, i.e., the vortex direction, of the silicon melt, a vortex fixation percentage, and a crystal yield of each of the monocrystalline silicon 5 manufacturing apparatuses 1, from #1 to #7, prior to performing the resistance setting step.

TABLE 1

| | | | | | | | Resistance | | Vortex | |
|---|---|---|---|---|---|---|---|---|---|---|
| | | | | | | | ratio | Vortex | fixation | Crystal |
| | R_{α} | R_{β} | R_{γ} | R_{δ} | R1 | R2 | (large/ | direction | percentage | yield |
| | (mΩ) | (mΩ) | (mΩ) | (mΩ) | (mΩ) | (mΩ) | small) | (%) | (%) | (%) |
| #1 | 2.15 | 1.89 | 2.21 | 2.96 | 4.04 | 5.17 | R2/R1 = 1.28 | Left | 100 | 100 |
| #2 | 2.84 | 2.85 | 2.32 | 3.39 | 5.69 | 5.71 | R2/R1 = 1.00 | Right/Left | 50 | 55 |
| #3 | 3.86 | 2.38 | 2.30 | 2.93 | 6.24 | 5.23 | R1/R2 = 1.19 | Right-dominant | 85 | 90 |
| #4 | 2.80 | 3.14 | 3.06 | 3.67 | 5.94 | 6.73 | R2/R1 = 1.13 | Left-dominant | 70 | 75 |
| #5 | 3.03 | 3.04 | 2.61 | 2.37 | 6.07 | 4.98 | R1/R2 = 1.22 | Right | 100 | 100 |
| #6 | 3.83 | 3.30 | 3.63 | 4.18 | 7.13 | 7.81 | R2/R1 = 1.10 | Right/Left | 60 | 65 |
| #7 | 2.71 | 2.65 | 2.52 | 2.78 | 5.36 | 5.30 | R1/R2 = 1.01 | Right/Left | 50 | 55 |

In FIG. 1, the first resistance value R1 is a sum of the contact resistances in the first heating region 4A, i.e., R1=R_{α}+R_{β}. The second resistance value R2 is a sum of the contact resistances in the second heating region 4B, i.e., R2=R_{γ}+R_{δ}. The resistance ratio is calculated by R1/R2 if R1>R2, and R2/R1 if R1<R2. The direction of the vortex is indicated as: “right” when the probability that the vortex is a clockwise vortex with the left side of FIGS. 6A and 6B being the upward flow and the right side being the downward flow is greater than or equal to 95%; “left” when the probability that the vortex is an anticlockwise vortex is greater than or equal to 95%; “right-dominant” when the probability that the vortex is the clockwise vortex is greater than or equal to 65% and less than 95%; “left-dominant” when the probability that the vortex is the anticlockwise vortex is greater than or equal to 65% and less than 95%; and “right/left” when the direction of the vortex does not correspond to any of the above, i.e., when there is not much difference between the probability that the vortex is the clockwise vortex and the probability that the vortex is the anticlockwise vortex.

The vortex fixation percentage indicates a percentage of the vortex direction fixed to the clockwise or anticlockwise when 100 pieces of monocrystalline silicon were grown by each of the seven monocrystalline silicon manufacturing apparatuses 1. The crystal yield indicates a percentage of the number of pieces of monocrystalline silicon in which, when 100 pieces of monocrystalline silicon were grown in each of the seven monocrystalline silicon manufacturing apparatuses 1, variation in oxygen concentration and variation in diameter, for example, satisfy a preset product standard.

Based on the results in Table 1, #1 and #5 each in which the resistance ratio between the first resistance value R1 and the second resistance value R2 was as large as greater than or equal to 1.20, achieved high values, i.e., 100% in vortex fixation percentage and 100% in crystal yield. Further, it was confirmed that the direction of the vortex was determined by the magnitudes of the first resistance value R1 and the second resistance value R2 that were respectively the sum of the contact resistances in the first heating region 4A and the sum of the contact resistances in the second heating region 4B. In each of #2, #6, and #7 having the ratio between the first resistance value R1 and the second resistance value R2 of greater than or equal to 1.00 and less than or equal to 1.10, the vortex fixation percentage was 50% to 60%, the vortex direction was random, and the crystal yield was low. In each of #3 and #4 having the ratio between the first resistance value R1 and the second resistance value R2 of greater than 1.10 and less than 1.20, the fixation of the vortex direction was not perfect and the crystal yield was lower than that of #1 and #5. Based on the results in Table 1, it was found that in Examples, the ratio between the first resistance value R1 and the second resistance value R2 making it possible to control the direction of the convection was greater than or equal to 1.20.

Next, the determination value was set to 1.2 based on the results in Table 1, and the resistance ratio between the first resistance value R1 and the second resistance value R2 was adjusted to be greater than or equal to the determination value by changing some of the contact resistances of the power supply portions 20A to 20D. Table 2 shows the results thereof.

TABLE 2

| | | | | | | | Resistance | | Vortex | |
|---|---|---|---|---|---|---|---|---|---|---|
| | | | | | | | ratio | Vortex | fixation | Crystal |
| | R_{α} | R_{β} | R_{γ} | R_{δ} | R1 | R2 | (large/ | direction | percentage | yield |
| | (mΩ) | (mΩ) | (mΩ) | (mΩ) | (mΩ) | (mΩ) | small) | (%) | (%) | (%) |
| #1 | 2.15 | 1.89 | 2.21 | 2.96 | 4.04 | 5.17 | R2/R1 = 1.28 | Left | 100 | 100 |
| #2 | 2.84 | 2.85 | 2.32 | 2.32 | 5.69 | 4.64 | R1/R2 = 1.23 | Right | 100 | 100 |
| #3 | 3.86 | 2.38 | 2.30 | 2.30 | 6.24 | 4.60 | R1/R2 = 1.36 | Right | 100 | 100 |
| #4 | 2.80 | 2.80 | 3.06 | 3.67 | 5.60 | 6.73 | R2/R1 = 1.20 | Left | 100 | 100 |
| #5 | 3.03 | 3.04 | 2.61 | 2.37 | 6.07 | 4.98 | R1/R2 = 1.22 | Right | 100 | 100 |
| #6 | 3.30 | 3.30 | 3.80 | 4.18 | 6.60 | 7.98 | R2/R1 = 1.21 | Left | 100 | 100 |
| #7 | 3.10 | 3.10 | 2.52 | 2.52 | 6.20 | 5.04 | R1/R2 = 1.23 | Right | 100 | 100 |

Table 2 shows resistance values after adjusting some of the contact resistances of Table 1. In other words, in each of #2 and #3, the contact resistance R_{α} was decreased by providing the conductive sheet 24 in the power supply portion 20D. In #4, the contact resistance R_{β} was decreased by providing the conductive sheet 24 in the power supply portion 20B.

In #6, the contact resistance R_{α} was decreased by providing the conductive sheet 24 in the power supply portion 20A, but this did not make the ratio to be greater than or equal to 1.2. Thus, the contact resistance R_{γ} was increased by applying the mechanical polishing to the power supply portion 20C having a lower contact resistance out of the power supply portions 20C and 20D.

In #7, the contact resistance R_{δ} was decreased by providing the conductive sheet 24 in the power supply portion 20D, and in addition, the contact resistances R_{α} and R_{β} were increased by applying the mechanical polishing to the power supply portions 20A and 20B.

The reason why the adjustment by providing the conductive sheet 24 is performed first is that disposing the conductive sheet 24 can be performed in a shorter time than the mechanical polishing. That is, the conductive sheet 24 only has to be disposed between any one of the terminals 21A to 21D and the corresponding one of the electrodes 22A to 22D, and be tighten by the nut 23A. The conductive sheet 24 can thus be disposed in a short time. In contrast, the mechanical polishing necessitates a polishing operation, which makes a working time longer. Further, there is also a risk of electric discharge during the crystal-growing process (upon high power loading).

Table 2 shows results in which the resistance ratio between the first resistance value R1 and the second resistance value R2 for each of the monocrystalline silicon manufacturing apparatuses 1, from #1 to #7, was set to the determination value of greater than or equal to 1.2, 100 pieces of monocrystalline silicon were grown by each of the monocrystalline silicon manufacturing apparatuses 1, and data thereof was tabulated. As shown in Table 2, the fixation percentage of the direction of the vortex of the silicon melt was improved to 100%, and the crystal yield was also greatly improved to 100%. Further, in the process after the direction of the vortex was fixed, no phenomenon was confirmed in which the vortex reversed during the growth of the monocrystalline silicon.

### Evaluation

Based on the results described above, it was confirmed that the direction of the convection of the silicon melt was completely fixed and the yield of the monocrystalline silicon was improved by: adjusting the contact resistances between the electrodes 22A to 22D and the terminals 21A to 21D of the respective power supply portions 20A to 20D; and setting the resistance ratio between the first resistance value R1 and the second resistance value R2 to be greater than or equal to the determination value. The first resistance value R1 was a sum of the contact resistances of the power supply portions 20A and 20B in the first heating region 4A. The second resistance value R2 was a sum of the contact resistances of the power supply portions 20C and 20D in the second heating region 4B.

Further, the upward flow of the silicon melt was dominant in the first heating region 4A or the second heating region 4B having a larger sum of the contact resistances, determining the direction of the convection (i.e., the direction of the vortex). That is, determination of the direction of the vortex was triggered by controlling the magnitudes of the contact resistances.

Furthermore, it was found that the resistance ratio at which the direction of the convection of the silicon melt was controllable was greater than or equal to “1.2” and the determination value only had to be set to “1.2” in the monocrystalline silicon manufacturing apparatus 1 of Examples.

Moreover, it was found that decreasing the resistance by interposing the conductive sheet 24 between the contact surfaces, or increasing the resistance by roughening the contact surface with use of the mechanical polishing was effective as measures to control the contact resistances of the power supply portions 20A to 20D. In addition, it was found that the method of adjusting the contact resistance value eliminated processing on the heat generating portion 30, the contact resistance value was adjustable at a worksite, and the method of adjusting the contact resistance value had an extremely high utility value.

### EXPLANATION OF CODES

1: monocrystalline silicon manufacturing apparatus, 2: chamber, 2A: quartz window, 3: crucible, 3A: graphite crucible, 3B: quartz crucible, 4: heating device, 4A: first heating region, 4B: second heating region, 5: support shaft, 6: heat insulation material, 7: pull-up shaft 7, 8: heat shield, 9: gas inlet, 10: exhaust outlet, 14: magnetic-field applying portion, 14A: first magnetic body, 14B: second magnetic body, 15: temperature sensor, 15A: reflector, 15B: radiation thermometer, 15C: reflection surface, 20A: power supply portion, 20B: power supply portion, 20C: power supply portion, 20D: power supply portion, 21A: terminal, 21B: terminal, 21C: terminal, 21D: terminal, 22A: electrode, 22B: electrode, 22C: electrode, 22D: electrode, 23A: nut, 23B: nut, 23C: nut, 23D: nut, 24: conductive sheet, 30: heat generating portion, 31: upper slit, 32: lower slit, 33A: first curve portion, 33B: second curve portion, 33C: third curve portion, 33D: fourth curve portion, 41: control device, 42: storage, 43: voltage applying portion, 44: resistance measurement portion, 45: display, 211A: connecting portion, 211B: connecting portion, 211C: connecting portion, 211D: connecting portion, 212A: through hole, 212B: through hole, 212C: through hole, 212D: through hole, 213A: top surface, 214A: bottom surface, 221A: body, 222A: top surface, 223A: insertion portion, 224A: male screw, 410: convection pattern control section, 420: pull-up control section, 430: resistance setting section, 431: resistance measurement control section, 432: resistance calculation section, 433: resistance ratio determination section, 434: resistance adjustment section, CA: center axis, CS: center, F: horizontal plane, L: radiation light, M: silicon melt, ML: arrow, P1: first measurement point, P2: second measurement point, R1: first resistance value, R2: second resistance value, R_{α}: contact resistance, R_{β}: contact resistance, R_{γ}: contact resistance, R_{δ}: contact resistance, S: surface, SC: seed crystal, SM: monocrystalline silicon, VL: imaginary line, W: heat generation amount, θ1: incidence angle, θ2: reflection angle, θf: angle

1. A method of manufacturing monocrystalline silicon of pulling up monocrystalline silicon from a silicon melt in a quartz crucible, the silicon melt having been heated using a heating device,
the heating device comprising: a heat generating portion disposed around the quartz crucible; and power supply portions configured to supply electric power to the heat generating portion,
the power supply portions comprising, in a case where the heating device is divided into a first heating region and a second heating region by a central magnetic field line of a horizontal magnetic field passing through a center axis of the quartz crucible viewed from vertically above, a first power supply portion disposed in the first heating region and a second power supply portion disposed in the second heating region,
the method comprising:
setting a first resistance value that is a resistance value of the first power supply portion and a second resistance value that is a resistance value of the second power supply portion;
heating the silicon melt in the quartz crucible in a magnetic-field-free state;
applying a horizontal magnetic field to the silicon melt in the quartz crucible; and
pulling up the monocrystalline silicon from the silicon melt, wherein
the setting of the resistance values comprises:
measuring the first resistance value and the second resistance value,
determining whether a resistance ratio is greater than or equal to a determination value that has been set in advance, the resistance ratio being a value obtained by dividing a higher resistance value by a lower resistance value out of the first resistance value and the second resistance value, and
adjusting, in a case where it is determined in the determination that the resistance ratio is less than the determination value, at least one of the first resistance value or the second resistance value,
executing again, in the case where it is determined in the determination that the resistance ratio is less than the determination value, the determination after executing the adjustment and the measurement; and
ending the setting of the resistance values in a case where it is determined in the determination that the resistance ratio is greater than or equal to the determination value.

2. The method of manufacturing the monocrystalline silicon according to claim 1, wherein
the setting of the resistance values is executed every time the pull-up of the monocrystalline silicon is executed a predetermined number of times.

3. The method of manufacturing the monocrystalline silicon according to claim 2, wherein
the predetermined number of times is greater than or equal to 1 and less than or equal to 50.

4. The method of manufacturing the monocrystalline silicon according to claim 1, wherein
the determination value is greater than or equal to 1.2.

5. The method of manufacturing the monocrystalline silicon according to claim 1, wherein
the measurement comprises:
measuring a combined resistance of the heat generating portion and the power supply portions,
measuring a combined resistance of the heat generating portion, and
calculating the first resistance value and the second resistance value based on respective resistance values obtained by the measurements.

6. The method of manufacturing the monocrystalline silicon according to claim 1, wherein
the power supply portions each comprise a terminal integrally provided with the heat generating portion, and an electrode having one end connected to the terminal and the other end connected to a power source, and
the adjustment comprises decreasing a resistance value of one of the power supply portions by disposing a conductive sheet between the terminal and the electrode.

7. The method of manufacturing the monocrystalline silicon according to claim 1, wherein
the power supply portions each comprise: a terminal connected to the heat generation portion; and an electrode having one end connected to the terminal and the other end connected to a power source, and
the adjustment comprises increasing a resistance value of one of the power supply portions by roughening a contact surface between the terminal and the electrode.

8. The method of manufacturing the monocrystalline silicon according to claim 1, wherein
the power supply portions each comprise: a terminal connected to the heat generation portion; and an electrode having one end connected to the terminal and the other end connected to a power source,
an electrical resistance adjuster having a plate shape is interposed between the terminal and the electrode, and
the adjustment comprises adjusting a resistance value by making the number of electrical resistance adjusters to be interposed between the terminal and the electrode of the first power supply portion different from the number of electrical resistance adjusters to be interposed between the terminal and the electrode of the second power supply portion, or by making a thickness dimension of the electrical resistance adjuster to be interposed between the terminal and the electrode of the first power supply portion different from a thickness dimension of the electrical resistance adjuster to be interposed between the terminal and the electrode of the second power supply portion.

9. A method of manufacturing a silicon wafer, the method comprising
manufacturing the silicon wafer by cutting out the silicon wafer from the monocrystalline silicon having been pulled up with use of the method of manufacturing the monocrystalline silicon according to claim 1.
